(19) United States
(12) Patent Application Publication
(10) Pub. No.: US 2009/0004399 A1
(43) Pub. Date: Jan. 1, 2009

(54) Tile Coating and Process Therefor

(76) Inventors: Andrew Leo Haynes, Auckland (NZ); Christopher John Nicholls, Auckland (NZ)

Correspondence Address: JACOBSON HOLMAN PLLC, 400 SEVENTH STREET N.W., SUITE 600, WASHINGTON, DC, 20004, US

(21) Appl. No.: 11/667,059

(22) PCT Filed: Nov. 4, 2005
(86) PCT No.: PCT/NZ05/00294

§ 371 Date: Jul. 7, 2008

(30) Foreign Application Priority Data
Nov. 4, 2004 (CA) 2486829

(51) Int. Cl. B05D 1/30; B05C 13/00; C23C 14/00

(52) U.S. Cl. 427/420; 118/500; 204/192.1

(57) ABSTRACT

The invention relates to a method of coating a substrate. A monomer in at least a partly flowable form is discharged from a melt blowing die and entrained in monomer in a flow of hot gas from at least one side of said melt blow die. The monomer is then deposited on a substrate by sputtering under positive pressure.

### FIELD OF INVENTION

The present invention relates to a process for coating a substrate with a plastic material and in particular, but not limited to, a process for coating tiles with a thermo plastic polyurethane.

### BACKGROUND

It is often desirable to improve the properties of 3-Dimensional objects, for example brittle objects, by coating the object with a protective layer. One such instance is tiles, in particular roofing tiles, as described below although it will be appreciated that the present invention is not limited to tiles. Tiles are typically made of a cementitious material, and as such, are brittle exhibiting a low modulus of rupture. For example, when exposed to thermal or physical forces tiles will often crack and fail completely breaking into pieces. Such behaviour is, of course, undesirable as the broken tiles destroy the integrity of the roof and must be replaced.

Accordingly, there is a need in the art to improve the performance characteristics of tiles. These characteristics are not limited to the modulus of rupture of the tiles, and include other properties such as UV resistance, application strength, microbe resistance, scratch resistance, chipping resistance, colour stability long term, batch colour stability, strength, water proofing of concrete enhanced, highly uv stable, non slip surface, mixture of colours applied at one time, are also desirable to be incorporated in a coating of a tile.

Existing technologies for coating tiles consist of wet based spray/shower coatings, for example slurry oxide, single and two pack paint systems. Such coatings are very susceptible to impact damage due to their cured nature, i.e. comprising thin flat layers of organic based pigments encapsulated in water, resin or petrochemical based carriers. These coatings evaporate leaving the base organic compounds which are typically stiff and inflexible. This renders the coating prone to chipping and cracking so that the coating no longer improves the tiles performance characteristics.

It is known to improve the performance characteristics of woven and fibrous materials by a melt blowing process in which a vacuum is applied to draw a molten polymer through a woven or fibrous substrate. Unfortunately such technologies are limited to the treatment of materials through which a vacuum can be drawn.

It is accordingly an object of the present invention to provide a tile coating which ameliorates at least some of the aforementioned problems in the art.

### BRIEF DESCRIPTION OF THE INVENTION

In a first aspect the present invention provides a method of coating a substrate comprising the steps of:

supplying to a melt blowing die a monomer in an at least partly flowable form,

discharging said monomer in a flowable state from said melt blowing die,

entraining said monomer in a flowable state in a flow of hot gas from at least one side of said melt blow die. and

depositing said monomer in a flowable state on a substrate by sputtering under positive pressure.

Preferably in the deposition step the monomer form a uniform coating on the substrate.

Preferably in the discharge step the monomer discharges through an aperture or apertures in the die.

Preferably the aperture or apertures have a diameter of between 0.1 mm to 3 mm.

Preferably there are between about 1 and about 70 apertures per square inch.

Preferably in the entraining step the gas is pressurised air.

Preferably the gas is heated to between about 40° C. to about 400° C.

Preferably the monomer is selected from the group comprising TPU, polypropylene, PVDF, EVA, PVC, Nylon, PC, Stryrene's, ABS, HDPE, LDPE and LLDPE.

Preferably the method further includes a preliminary step of melting the substrate by heating to a temperature of between about 40° C. and about 400° C.

Preferably the substrate is heated to a temperature of between about 140° C. and about 195° C.

Preferably the method further includes a preliminary step of heating the monomer to a temperature of between about 40° C. and about 400° C.

Preferably the monomer is Thermoplastic Polyurethane (TPU).

Preferably the monomer is heated to a temperature of between about 210° C. and about 245° C.

Preferably the substrate is selected from the group comprising cements, aggregates, geopolymers, natural stones, tin, aluminium, stainless steel, plastic and resinous materials, fibreglass matt and cloth, cotton, hemp cloth, jute cloth.

Preferably the method includes a step of controlled cooling of the substrate after deposition.

Preferably the method includes a step of dipping the coated substrate in a water bath after deposition.

Preferably the coating deposited on the substrate is between 10 microns to 1 mm thick.

Preferably in the depositing step the entrained polymer is at an angle of between 15° to 165° relative to the surface of the substrate. In a second aspect the present invention provides a positive pressure apparatus to deposit a coating on a substrate comprising:

a melt blowing die having an aperture or apertures through which a flowable monomer resin is discharged;

a means for supplying the flowable monomer to the melt blowing die;

a pressurised gas supply configured to entrain the flowable monomer resin as it discharges from the die; and

a support table to position the substrate relative to the die so that the substrate is coated by the entrained monomer.

Preferably the melt blowing die includes a head having an array of apertures through which the monomer discharges.

Preferably the apertures have a diameter of between 0.1 mm to 3 mm.

Preferably there are between about 1 and about 70 apertures per square inch.

Preferably the positioning table is stationary and the melt blowing die can be moved to a position where the entrained monomer resin can coat the or each substrate.

Alternatively the positioning table is a conveyor capable of advancing the or each substrate to a position where the entrained monomer resin can coat the or each substrate.

Preferably the entrained polymer can be deposited at an angle of between 15° to 165° relative to the surface of the substrate.

In a third aspect the present invention provides a coated substrate when prepared accordingly to a method described above.

In a further aspect the present invention provides a melt blow process comprising applying a plastic coating to the surface of a tile.

In another aspect the present invention consists in a tile coating of a plastic coating or plastic film.

Preferably the plastic film is one formed prior to application to a tile.

Preferably the plastic film is one extruded directly onto a surface of a tile.

Preferably the tile coating is a thermoplastic material.

Preferably said thermo plastic material is polyurethane.

Preferably said polyurethane includes a uv stabilizing additive.

Preferably said polyurethane includes a fire retardant additive.

Preferably said plastic film is adhesion applied to a said tile.

Preferably said plastic coating is a sprayed layup.

Preferably said plastic layup is a fibre re-enforced sprayed layup.

In another aspect the present invention consists in a method coating a tile (preferably a concrete tile) comprising applying a plastic coating to at least part of a surface of a said tile.

Preferably said applying is by extruding a sheet formed plastic coating directly to said tile.

Preferably the extruded sheet is at a temperature to still at least be tacky prior to it being deposited onto a surface of said tile.

Preferably said applying is by melt blowing the plastic coating onto said tile.

Preferably said applying is by a spay deposition of a non woven precursor form of the plastic coating.

Preferably said coating is applied to a thickness of between 10 microns to 1 mm.

In a further aspect the present invention consists in a tile which includes a coating of a plastic coating or plastic film.

Preferably the plastic film is one formed prior to application to a tile.

Preferably the plastic film is one extruded directly onto a surface of a tile.

Preferably the tile coating is a thermoplastic material.

Preferably said thermo plastic material is a polyurethane.

Preferably said polyurethane includes a uv stabilizing additive.

Preferably said polyurethane includes a fire retardant additive.

Preferably said plastic film is adhesion applied to a said tile.

Preferably said plastic coating is a sprayed layup.

Preferably said plastic layup is a fibre re-enforced sprayed layup.

This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth. For the purposes of illustrating the invention, there is shown in the drawings a form which is presently preferred. It is being understood however that this invention is not limited to the precise arrangements shown.

As used herein the following terms have the meanings as specified below:

The term ‘monomer’ includes monomers and derivatives thereof, for example dimmers, polymers and salts thereof.

The term ‘comprising’ as used in this specification and claims means ‘consisting at least in part of’, that is to say when interpreting independent claims including that term, the features prefaced by that term in each claim will need to be present but other features can also be present.

The term ‘entrained’ refers to discharged filaments of monomer resin carried in a flow of gas.

A preferred form and methodologies of the present invention will now be described with reference to the accompanying drawings.

### BRIEF DESCRIPTION OF THE DRAWINGS

FIG. 1 is a schematic diagram of a positive pressure coating apparatus of the present invention,

FIG. 2 is a top view of a bear tile prior to impact testing,

FIG. 3 is a top view of a bear tile after impact testing,

FIG. 4 is a top view of an oxide treated tile after impact testing,

FIG. 5 is a side view of a coated tile of the present invention,

FIG. 6 is a top view of a coated tile of the present invention prior to impact testing,

FIG. 7 is a top view of a coated tile of the present invention after a first impact test,

FIG. 8 is a top view of a coated tile of the present invention after a second impact test, and

FIG. 9 is a back view of a coated tile of the present invention after a second impact test.

### DETAILED DESCRIPTION OF THE INVENTION

The tile coating technology we have developed enables concrete tiles to be coated with a highly UV stabilised Thermo Plastic Polyurethane. This technology enables the outer exposed surface of a concrete tile to be coated with a vastly superior colouring agent at a similar cost to the currently used Oxide slurries and paints.

This coating also provides the tile with significant strength and durability benefits. This is particularly so if the thickness of the coating is increased to over about 100 microns. The technology in the specifically designed machinery to enable the coating such as by extrusion coating or by melt blown deposition.

The Thermoplastic includes a uv stabilising additive and may include a flame retardant.

The thermoplastic material may have properties such as UV resistance, application strength, microbe resistance, scratch resistance, chipping resistance, colour stability long term, batch colour stability, strength, water proofing of concrete enhanced, highly uv stable, non slip surface, mixture of colours applied at one time.

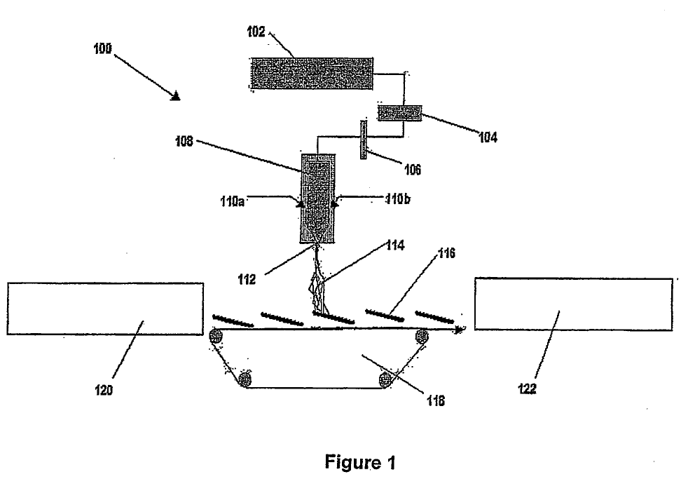

A preferred process for coating a tile will now be described with reference to FIG. 1 which illustrates a positive pressure apparatus 100. A Thermo Plastic Polyurethane (TPU) is heated in extruder 102 to a flowable molten state. Desirably the monomer resin is preheated before introduction into the extruder 102, to ensure a satisfactory moisture content of, for example 0.1%. Heat may be applied to the monomer resin throughout the deposition process to ensure it is maintained in a flowable state. However it is also contemplated that a light cure monomer resin could be employed in the present invention, in which instance no heating step may be necessary for the resin to be in a sufficiently flowable state for introduction into the extruder 102.

Typical temperatures will be between 210 to 245° C. The TPU is then pumped by gear pump 106 through filter 104 to remove any undesirables from the TPU resin Undesirables include any solid particulates that may subsequently block the apertures of the melt blowing die.

The TPU is pumped into the melt blowing die 108 and is discharged via apertures 112. While in FIG. 3 the apertures 112 are formed on a single head of the die 108, it is within the scope of the invention to provide multiple die heads allowing the molten TPU to be simultaneously or sequentially discharged from different angles relative to the substrate tile 116.

As the TPU is discharged it becomes entrained in jets of pressured air 110a and 110b at between 40 to 400° C. The temperature of the jets of pressurised air is matched to the resin being discharged. Typically the air temperature will be between 15° C. below or 400° C. above the viscount softening point of the resin, preferably about 20° C. above or below the melting point of the resin. The flow rate of the air is dependant on the type, temperature and quantity of the resin being deposited. For example, some resins can be processed at air speeds as low as 5 ms⁻¹, while other resins having a higher viscosity require an air flow speed of between 4 to 500 ms−1 to be correctly orientated or blown in a consistent direction.

This combination of pressurised heated air entraining TPU filaments forms a curtain 114 which is deposited onto the surface of a substrate tile 116. The substrate tile may be pre-treated by heating up to between 60° C. to 285° C., preferably between 140° C. to 195° C. in drying and heating chamber 120.

In one embodiment the heating chamber is a tunnel of sufficient length to allow a tile passing therethrough to be heated/dried to a desired temperature. Providing a tunnel of sufficient length to heat the tile must be balanced against maintaining an acceptable production speed. The required thickness of the tile coating, the desired peel strength, the tile surface and the type of resin being deposited all influence the temperature to which the tile is heated. A typical heater for the tile is an IR heater bank, although other heaters such as flame, hot air, among others are also possible.

Without wish to be bound to any particular theory it is believed that by sputtering the molten TPU onto a preheated tile surface the viscosity of the molten TPU is maintained allowing the TPU to flow on the surface of the tile to form a uniform layer. Additionally, by maintaining the viscosity of the TPU, the TPU is able to impregnate into the pores of the tile and achieve a mechanical bond between the tile and the TPU layer. This results in the high peel strength characteristics of the coatings prepared according to the present invention.

When the substrate tile is non-porous, for example an aluminium tile, an etching agent may be used to roughen the surface of the tile and encourage the formation of a mechanical bond between the TPU layer and the tile. Additionally any number of known in the art adhesives may be employed to improve the bonding of the TPU layer to the tile.

The substrate tile 116 is advanced by conveyor 118 to a position proximate the die 108 where it is coated by the molten TPU entrained in the pressurised air flow. The speed of the conveyor can be between 1 and 300 mls/min. Once the coating is complete the substrate tile 116 is removed. Alternatively the substrate tile 116 may be held in position by a support table and the melt blowing die moved to coat the tile with the TPU. The melt blowing die may be moveable to both track over the substrate tile 116, as well as being movable to discharge the molten TPU from varying angles relative to the substrate tile 116 and thereby achieve a desired coating.

The coated substrate tile may be subsequently treated in a cooling chamber 122 to control the cooling of the tile and maximise the bonding of the TPU layer to the tile. The coated tile may also be treated in a hot water bath to produce a glazed surface on the tile.

Desirably any monomer resin overspray from the coating process is recycled.

The process and apparatus described above is amenable to a number of variations for uptake in other industries. For example, the present invention may combine with Photo Voltaic technology to provide improved solar energy systems. A substrate tile may be first primed by depositing a base layer of TPU in accordance with the present invention. A photo voltaic cell can then be screen printed atop the TPU layer according to known in the art processes and finally a sealing top coat of aliphatic TPU can be deposited onto the PV cell. This arrangement will protect the PV cell from weathering and allow an entire roof to be tiled with solar cells.

Additionally the process and apparatus described above can be arranged to deposit multiple coatings upon a substrate, either by providing multiple melt blowing die head or by repeatedly passing a substrate through the apparatus/process.

In another embodiment of a multi layer coating process a polycarbonate layer is deposited onto a rigid substrate and a TPU layer is coated atop the polycarbonate layer. The polycarbonate layer can then be separated from the rigid substrate to provide a TPU coated polycarbonate product. Such coated substrates can have selected properties, for example being both light weight and photo stable.

The present invention coats a tile substrate with a polymer based resin, with the coating improving the impact characteristics of the tile. The coating has been found to absorb the initial impact shocks without chipping or cracking. Furthermore even when an impact is sufficiently high so as to crack the tile, the polymer based resin coating will remain and hold the tile together. The methodology and results of the experiments are outlined below:

Impact Testing

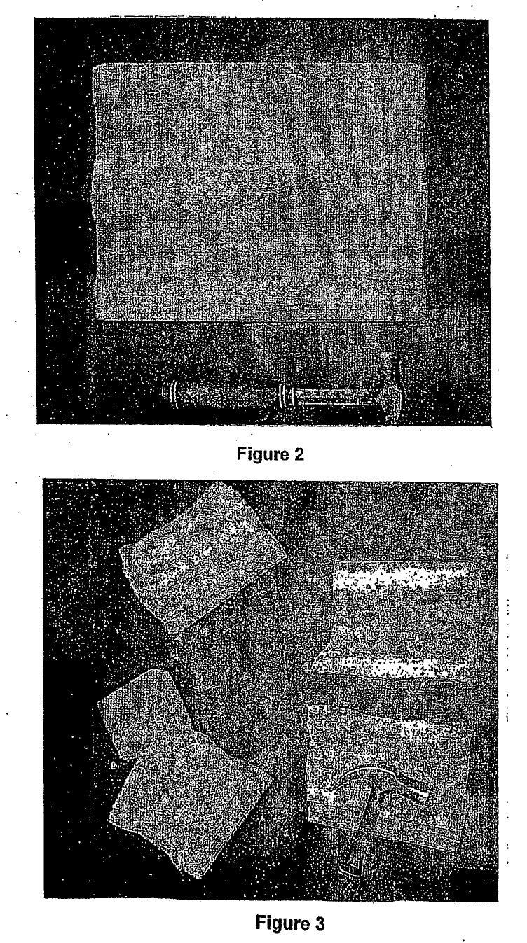

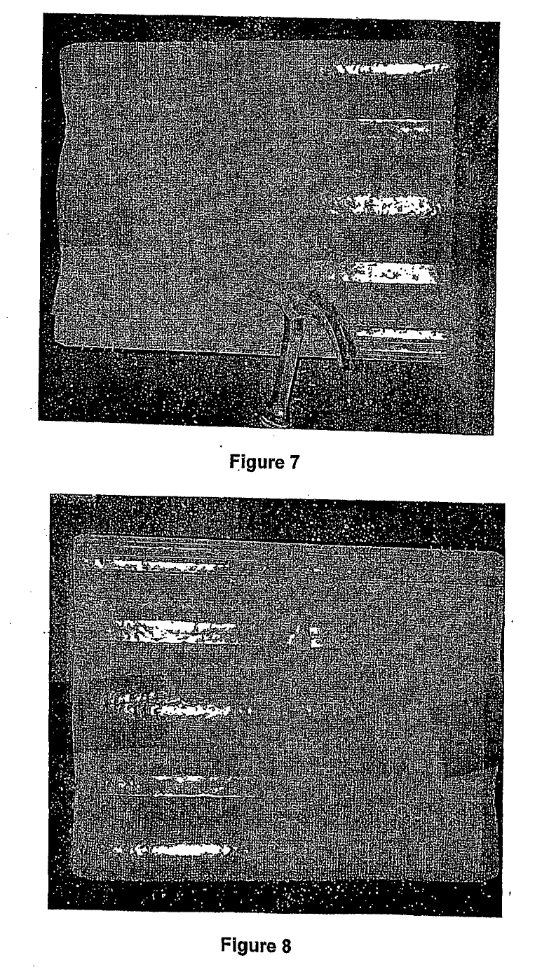

The tests were conducted supporting one end of a tile on a 100 mm wooden block to place the tile in a condition having a 4:1 pitch ratio. A 24 oz hammer was dropped from a height of 2000 mm on a bear tile, an oxide treated tile and a TPU coated tile respectively. The results of the testing are set out in FIGS. 2 to 9.

The TPU coated tile was prepared in accordance with the method described above by preheating the a tile for 65 seconds at 100% reflective heat so that the surface of the tile reached a temperature of between 185° C. The TPU resin was heated to a melt temperature of 265° C. and entrained in a 200 ms⁻¹ flow of pressurised air and coated onto a tile at a thickness of around 100 microns.

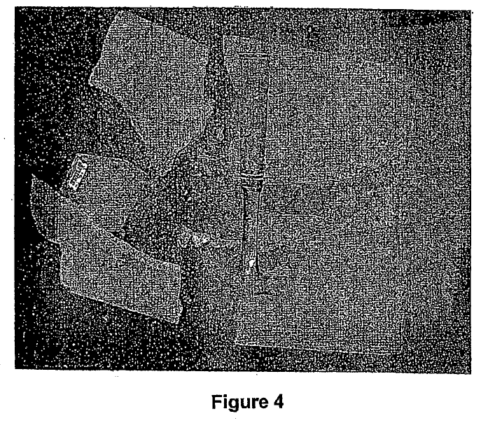

FIGS. 2 and 3 show a bear tile before and after impact testing. The bear tile shattered into smaller pieces. Similarly FIG. 4 shows the oxide treated tile also shattered into smaller pieces.

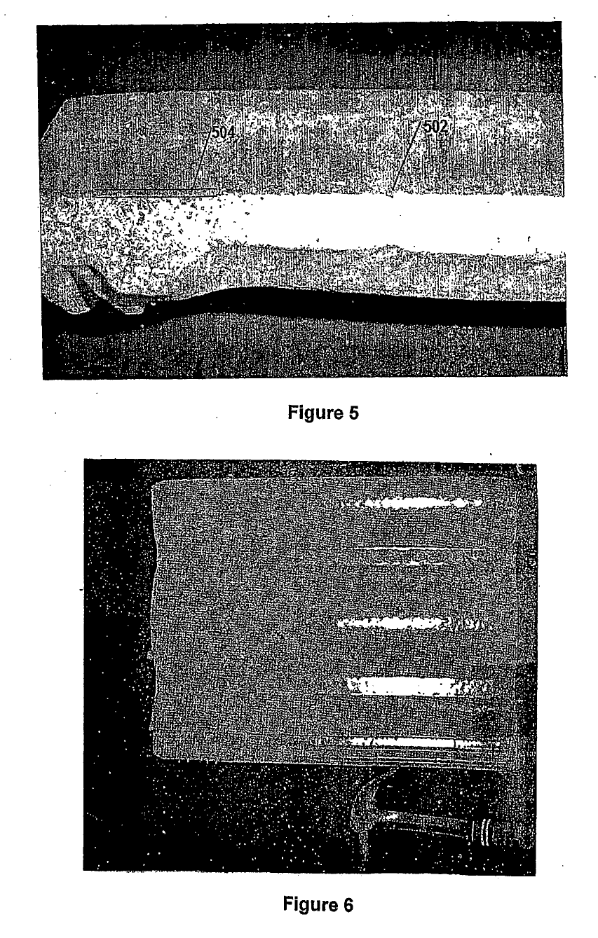

FIG. 5 shows a sectional view of an edge of the TPU coated tile. The tile had a TPU coating thickness 504 of around 100 microns. FIG. 5 also shows the penetration of the TPU coating 504 into the tile to form a mechanical bond between the coating and the tile.

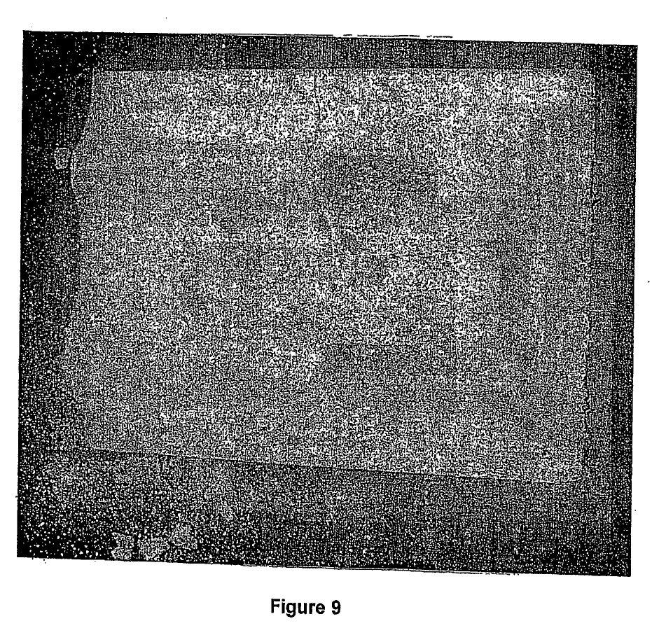

FIGS. 6, 7 and 8 show a tile prior to impact testing, after one impact test and after a second impact test respectively. FIG. 9 shows the reverse side of the tile after the second impact test. After the first impact the tile substrate had shattered, but remained held together by the TPU coating. Even after the second impact test the tile substrate remained together.

The tiles not only remain held together, but are strongly held together due to the strength of the bond between the TPU coating and the tile substrate. Further testing was performed on a series of coated tiles prepared under varying process conditions to show the high bond strength between the TPU coating and the tile. This was done by measuring the load required to separate the TPU layer from the tile. The results are set out in Table 1 below:

TABLE 1
Tile coating parameters and peel strengths

| | | Melt | Coating | Tile preheat | Air | Peel strength |
|---|---|---|---|---|---|---|
| Test | Resin | temp | gauge | temperature | speed | range |
| number | Type | C. | um | C. | mts/sec | Load (N) |
| 1 | TPU | 230 | 60 | 130 | 200 | 101-148 |
| 2 | TPU | 230 | 100 | 120 | 200 | 101-119 |
| 3 | TPU | 230 | 120 | 85 | 200 | 35-41 |

1-32. (canceled)

33. A method of coating a substrate comprising the steps of:
supplying to a melt blowing die a monomer in an at least partly flowable form,
discharging said monomer in a flowable state from said melt blowing die,
entraining said monomer in a flowable state in a flow of hot gas from at least one side of said melt blow die and
depositing said monomer in a flowable state on a substrate by sputtering under positive pressure to form a film coating on said substrate.

34. The method as claimed in claim 33 wherein in the deposition step the monomer forms a uniform said film coating on the substrate.

35. The method as claimed in claim 34 wherein in the discharge step the monomer discharges through an aperture or apertures in the die.

36. The method as claimed in claim 35 wherein said aperture or apertures have a diameter of between 0.1 mm to 3 mm.

37. The method as claimed in claim 36 wherein there are between about 1 and about 70 said apertures per square inch.

38. The method as claimed in claim 37 wherein in the entraining step said gas is pressurised air.

39. The method as claimed in claim 38 wherein said gas is heated to between about 40° C. to about 400° C.

40. The method as claimed in claim 39 wherein said monomer is selected from the group comprising TPU, polypropylene, PVDF, EVA, PVC, Nylon, PC, Stryrenes, ABS, HDPE, LDPE and LLDPE.

41. The method as claimed in claim 40 wherein the method further includes a preliminary step of heating said substrate to a temperature of between about 40° C. and about 400° C.

42. The method as claimed in claim 41 wherein said substrate is heated to a temperature of between about 140° C. and about 195° C.

43. The method as claimed in claim 42 wherein said method further includes a preliminary step of heating said monomer to a temperature of between about 40° C. and about 400° C.

44. The method as claimed in claim 43 wherein said monomer is Thermoplastic Polyurethane (TPU).

45. The method as claimed in claim 44 wherein said monomer is heated to a temperature of between about 210° C. and about 245° C.

46. The method as claimed in claim 45 wherein said substrate is selected from the group comprising cements, aggregates, geopolymers, natural stones, tin, aluminium, stainless steel, plastic and resinous materials, fibreglass matt and cloth, cotton, hemp cloth, jute cloth.

47. The method as claimed in claim 46 wherein the method includes a step of controlled cooling of said substrate after deposition.

48. The method as claimed in claim 47 wherein the method includes a step of dipping said coated substrate in a water bath after deposition.

49. The method as claimed in claim 48 wherein said substrate is of three dimensional or contoured form.

50. The method as claimed in claim 49 wherein the coating deposited on said substrate is between 10 microns to 1 mm thick.

51. The method as claimed in claim 50 wherein in the depositing step the entrained polymer is at an angle of between 15° to 165° relative to the surface of said substrate.

52. A positive pressure apparatus to deposit a coating on a substrate comprising or including:
a melt blowing die having an aperture or apertures through which a flowable monomer resin is discharged,
a supply of said flowable monomer resin to said melt blowing die,
a pressurised gas supply configured to entrain said flowable monomer resin as it discharges from said melt blowing die; and
a support table to position said substrate relative to said melt blowing die so that said substrate is film coated by said entrained flowable monomer resin.

53. The positive pressure apparatus as claimed in claim 52 wherein said melt blowing die includes a head having an array of apertures through which said flowable monomer resin discharges.

54. The positive pressure apparatus as claimed in claim 53 wherein said apertures have a diameter of between 0.1 mm to 3 mm.

55. The positive pressure apparatus as claimed in claim 53 wherein there are between about 1 and about 70 said apertures per square inch.

56. The positive pressure apparatus as claimed in claim 55 wherein said positioning table is stationary and said melt blowing die can be moved to a position where said entrained flowable monomer resin can coat the or each said substrate.

57. The positive pressure apparatus as claimed claim 55 wherein said positioning table is a conveyor capable of advancing the or each said substrate to a position where said entrained flowable monomer resin can coat the or each said substrate.

58. The positive pressure apparatus as claimed in claim 57 wherein said entrained flowable monomer resin can be deposited at an angle of between 15° to 165° relative to the surface of the substrate.

59. The coated substrate when prepared accordingly to a method of claim 33.

60. A melt blow process comprising or including applying a plastic coating to the surface of a tile.

61. The method as claimed in claim 33, substantially as herein described with reference to any Example thereof and with or without reference to the accompanying drawings.

62. The positive pressure apparatus as claimed in claim 52, substantially as herein described with reference to any Example thereof and with or without reference to the accompanying drawings.

63. The coated substrate as claimed in claim 59, substantially as herein described with reference to any Example thereof and with or without reference to the accompanying drawings.

64. The melt blow process as claimed in claim 60, substantially as herein described with reference to any Example thereof and with or without reference to the accompanying drawings.
